(19) United States
(12) Patent Application Publication
(10) Pub. No.: US 2023/0246411 A1
(43) Pub. Date: Aug. 3, 2023

(54) LIGHT EMITTING DEVICE

(71) Applicant: SONY SEMICONDUCTOR SOLUTIONS CORPORATION, Kanagawa (JP)

(72) Inventor: Takeshi YUWAKI, Kumamoto (JP)

(73) Assignee: SONY SEMICONDUCTOR SOLUTIONS CORPORATION, Kanagawa (JP)

(21) Appl. No.: 18/004,793

(22) PCT Filed: Jul. 9, 2021
(86) PCT No.: PCT/JP2021/025939

§ 371 Date: Jan. 9, 2023

(30) Foreign Application Priority Data
Jul. 20, 2020 (JP) 2020-124070

(51) Int. Cl. H01S 5/023; H01S 5/42; H01S 5/042; G01S 17/10; G01S 7/481; G01S 7/4865

(52) U.S. Cl. CPC H01S 5/023; H01S 5/423; H01S 5/042; G01S 17/10; G01S 7/4815; G01S 7/4865

(57) ABSTRACT

A light emitting device with a light emitter, an output unit, and a drive current supply wiring is provided. The light emitter, includes a plurality of light emitting elements. The output unit includes a plurality of output pads. The drive current supply wiring supplies the drive current from a power supply to the light emitting elements via the output pads, and includes an annular wiring, a common wiring, and a connection wiring. The annular wiring annularly surrounds and is connected to the plurality of output pads in a predetermined number of rows, and is arranged in a column direction of the output pads. The common wiring is on both sides in a direction orthogonal to an arrangement direction of a plurality of annular wirings and in parallel with the arrangement direction, and is connected to the power supply. The connection wiring connects the annular wiring and the common wiring.

### FIELD

The present disclosure relates to a light emitting device.

### BACKGROUND

There is a light emitting device of a distance measuring system capable of emitting light with various light emitting patterns by individually controlling driving of a plurality of light emitting elements provided in a matrix in plan view.

In this light emitting device, since a wiring length becomes longer as the light emitting elements are farther from a power supply than the light emitting elements closer to the power supply, a voltage drop becomes larger as compared with that of the light emitting elements closer to the power supply and thus a drive current decreases. As a result, luminance unevenness occurs due to decreased light emission luminance.

For this reason, there is a light emitting device in which a wiring width of a bus connecting a group of light emitting elements in several rows adjacent in a column direction (hereinafter referred to as “stage”) and a power supply is widened as a bus is connected to a stage farther from the power supply to reduce a wiring resistance and suppress the voltage drop (for example, Patent Literature 1). As a result, the light emitting device reduces the luminance unevenness between the stages.

### CITATION LIST

### Patent Literature

Patent Literature 1: JP 2012-226360 A

### SUMMARY

### Technical Problem

However, in the above conventional technique, a luminance unevenness between stages can be reduced, but the luminance unevenness in a group of light emitting elements in several rows adjacent in a column direction cannot be suppressed.

Therefore, the present disclosure proposes a light emitting device capable of suppressing the luminance unevenness in the group of light emitting elements in several rows adjacent in the column direction.

### Solution to Problem

According to the present disclosure, a solid-state imaging device is provided. A light emitting device includes a light emitter, an output unit, and a drive current supply wiring. In the light emitter, a plurality of light emitting elements is provided in a matrix. The output unit is provided with a plurality of output pads that outputs a drive current to the light emitting elements, and the output pads overlap with the light emitting elements in plan view. The drive current supply wiring is provided in a wiring layer, and supplies the drive current from a power supply to the light emitting elements via the output pads. The drive current supply wiring includes an annular wiring, a common wiring, and a connection wiring. The annular wiring annularly surrounds the plurality of output pads in a predetermined number of rows, is connected to the output pads surrounded, and is arranged in a column direction of the output pads. The common wiring is provided on both sides in a direction orthogonal to an arrangement direction of a plurality of annular wirings and in parallel with the arrangement direction, and is connected to the power supply. The connection wiring connects the annular wiring and the common wiring.

### BRIEF DESCRIPTION OF DRAWINGS

FIG. 1 is a diagram illustrating a configuration example of a distance measuring apparatus according to the present disclosure.

FIG. 2 is a diagram illustrating an arrangement of a drive circuit and a light emitter according to the present disclosure.

FIG. 3 is a plan view illustrating a drive circuit according to the present disclosure.

FIG. 4 is a plan view illustrating a drive current supply wiring according to a comparative example.

FIG. 5 is a table of an error rate of a drive current in each area in which the drive current is supplied to each output pad when the drive current supply wiring according to the comparative example is adopted.

FIG. 6 is a plan view illustrating a drive current supply wiring according to the present disclosure.

FIG. 7 is a table of an error rate of the drive current in each area in which the drive current is supplied to each output pad when the drive current supply wiring according to the present disclosure is adopted.

FIG. 8 is a cross-sectional view illustrating the drive current supply wiring according to the present disclosure.

FIG. 9 is a cross-sectional view illustrating a drive current supply wiring according to a modified example of the present disclosure.

### DESCRIPTION OF EMBODIMENTS

Hereinafter, embodiments of the present disclosure will be described with reference to the drawings. In each of the following embodiments, same parts are given the same reference signs to omit redundant description.

### 1. Distance Measuring Apparatus

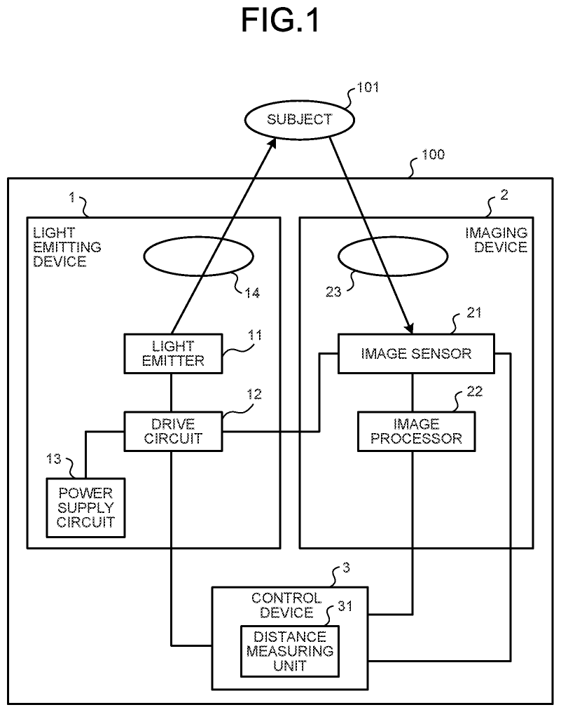

First, a configuration of a distance measuring apparatus including a light emitting device according to the present disclosure will be described with reference to FIG. 1. FIG. 1 is a diagram illustrating a configuration example of the distance measuring apparatus according to the present disclosure. A distance measuring apparatus 100 according to the present disclosure is an apparatus that calculates a distance to a distance measuring object by, for example, an Indirect Time of Flight (ToF) system.

In the Indirect ToF system, irradiation light is emitted toward an object, reflected light returned after the irradiation light is reflected on a surface of the object is detected, a time from emission of the irradiation light to reception of the reflected light is detected as a phase difference, and a distance to the object is calculated based on the phase difference.

As illustrated in FIG. 1, the distance measuring apparatus 100 according to the present disclosure includes a light emitting device 1, an imaging device 2, and a control device 3. The light emitting device 1 includes a light emitter 11, a drive circuit 12, a power supply circuit 13, and a light-emitting side optical system 14. The imaging device 2 includes an image sensor 21, an image processor 22, and an imaging side optical system 23.

The control device 3 includes a distance measuring unit 31. The control device 3 may be included in the light emitting device 1 or the imaging device 2, or configured separately from the light emitting device 1 and the imaging device 2.

The light emitter 11 includes a plurality of light emitting elements that emits laser light and is arranged in a matrix in plan view. Each of the plurality of light emitting elements includes, for example, a vertical cavity surface emitting laser (VCSEL) and functions as a light source of structured light.

The drive circuit 12 includes an electric circuit that drives the light emitter 11. For example, the power supply circuit 13 generates a power supply voltage of the drive circuit 12 from an input voltage supplied from a battery (not illustrated) or the like provided in the distance measuring apparatus 100. The drive circuit 12 supplies the power supply voltage (drive current) to the light emitter 11 to drive the light emitter 11.

A subject 101 that is a distance measuring target is irradiated with light emitted from the light emitter 11 via the light-emitting side optical system 14. Then, reflected light from the subject 101 of the light irradiated in this manner enters an imaging surface of the image sensor 21 via the imaging side optical system 23.

The image sensor 21 includes, for example, an imaging element such as a charge coupled device (CCD) sensor or a complementary metal oxide semiconductor (CMOS) sensor, and receives the reflected light from the subject 101 entering via the imaging side optical system 23 as described above, photoelectrically converts the reflected light into an electrical signal, and outputs the electrical signal.

The image sensor 21 performs, for example, a correlated double sampling (CDS) process, an automatic gain control (AGC) process, and the like on the electrical signal obtained by photoelectrically converting the received light, and further performs an analog/digital (A/D) conversion process.

Then, the image sensor 21 outputs an image signal as digital data to the image processor 22 in a subsequent step. Furthermore, the image sensor 21 outputs a frame synchronization signal to the drive circuit 12. As a result, the drive circuit 12 can cause a light emitting element 321 in the light emitter 11 to emit light at a timing corresponding to a frame period of the image sensor 21.

Note that a signal indicating a light emission timing of the light emitter 11 may be output from the drive circuit 12 to the image sensor 21, and the image sensor 21 may receive the reflected light at a light reception timing shifted by a predetermined phase from the light emission timing.

The image processor 22 includes, for example, an image processing processor such as a digital signal processor (DSP). The image processor 22 performs various image signal processes on a digital signal (image signal) input from the image sensor 21.

The control device 3 includes, for example, a microcomputer including a central processing unit (CPU), a read only memory (ROM), a random access memory (RAM), and the like, or an information processing device such as a DSP. The control device 3 performs control of the drive circuit 12 for controlling a light emitting operation by the light emitter 11 and control related to an imaging operation by the image sensor 21.

In addition, the control device 3 has a function as the distance measuring unit 31. The distance measuring unit 31 measures a distance to the subject 101 based on the image signal input through the image processor 22 (i.e., image signal obtained by receiving the reflected light from the subject 101).

Furthermore, in order to enable identification of a three-dimensional shape of the subject 101, the distance measuring unit 31 measures a distance to each part of the subject 101. In addition, the control device 3 may be configured to control the power supply circuit 13.

Here, a specific distance measuring method in the distance measuring apparatus 100 will be described. As the distance measuring method in the distance measuring apparatus 100, for example, a distance measuring method using a structured light (STL) system or a time of flight (ToF) system can be adopted.

The STL system measures a distance based on an image obtained by capturing the subject 101 irradiated with light having a predetermined light/dark pattern such as a dot pattern or a lattice pattern.

In the STL system, the subject 101 is irradiated with pattern light having the dot pattern. The pattern light is divided into a plurality of blocks, and a different dot pattern is assigned to each of the plurality of blocks, so that the dot patterns do not overlap between the blocks. When the STL system is adopted, the light emitter 11 functions as a light source of the STL.

Furthermore, the ToF system measures a distance to an object by detecting a flight time (time difference) of light emitted from the light emitter 11 until reaching the image sensor 21 after the light is reflected by the object.

When a so-called direct ToF system is adopted as the ToF system, a single photon avalanche diode (SPAD) is used as the image sensor 21, and the light emitter 11 is driven by pulses.

In this case, the distance measuring unit 31 calculates a time difference from light emission to light reception of light emitted from the light emitter 11 and received by the image sensor 21 based on the image signal input via the image processor 22 to calculate a distance to each part of the subject 101 based on the time difference and a light speed.

Note that, when a so-called indirect ToF system (phase difference method) is adopted as the ToF system, for example, an infrared light (IR) image sensor is used as the image sensor. When the ToF system is adopted, the light emitter 11 functions as a light source of the ToF sensor.

### 2. Arrangement of Drive Circuit and Light Emitter

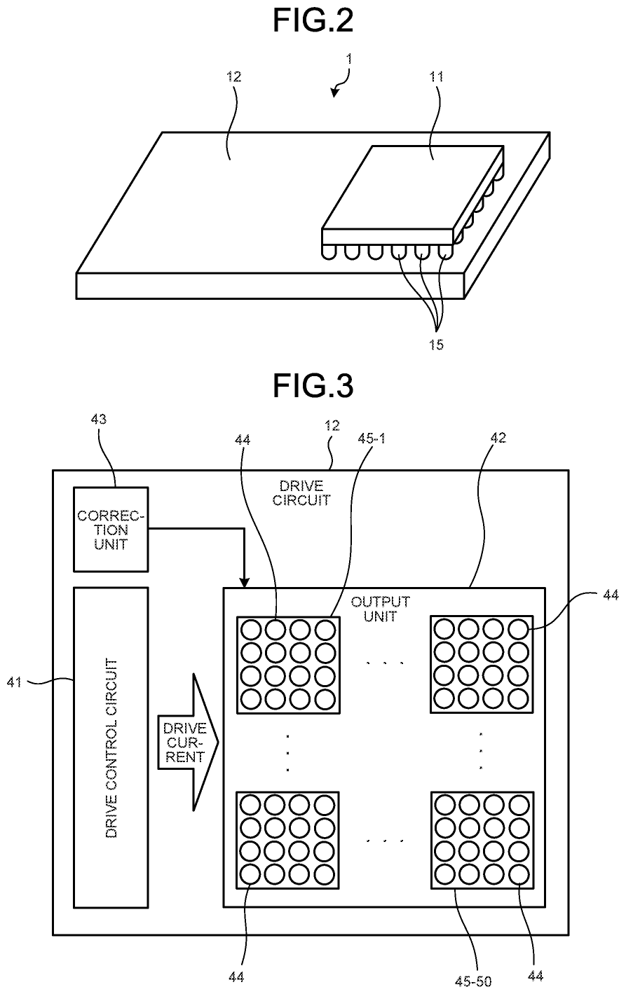

FIG. 2 is a diagram illustrating an arrangement of the drive circuit and the light emitter according to the present disclosure. As illustrated in FIG. 2, the light emitter 11 is stacked on the drive circuit 12. Thus, the light emitting device 1 can be downsized by reducing an occupied area as compared with a case where the light emitter 11 and the drive circuit 12 are placed flat on the same plane.

The plurality of light emitting elements is provided on an upper surface of the light emitter 11 in a matrix in plan view. On a lower surface of the light emitter 11, an input pad to which the drive current of the light emitting element is input is provided at a position overlapping each light emitting element in plan view.

On the other hand, on an upper surface of the drive circuit 12, an output pad that outputs the drive current to the input pad is provided at a position overlapping the input pad of the light emitter 11 in plan view. Each output pad and each input pad are connected by a bump 15.

### 3. Configuration of Drive Circuit

FIG. 3 is a plan view illustrating the drive circuit according to the present disclosure. In the following description, for convenience, a column direction of the light emitting element, a column direction of the output pad, and an arrangement direction of an annular wiring described later in plan view are referred to as a Y direction, and a row direction of the light emitting element, a row direction of the output pad, and a direction orthogonal to the arrangement direction of the annular wiring in plan view are referred to as an X direction.

As illustrated in FIG. 3, the drive circuit 12 includes a drive control circuit 41, an output unit 42, and a correction unit 43. The drive control circuit 41 supplies the drive current to a plurality of output pads 44 provided in a matrix in plan view in the output unit 42 via a drive current supply wiring described later. Note that the drive control circuit 41 also performs control to output, to the output unit 42, a selection signal to emit light among the plurality of light emitting elements provided in the light emitter 11.

The correction unit 43 divides a region provided with the plurality of output pads 44 in the output unit 42 into a plurality of areas, and corrects the drive current supplied to each area of the output pads 44. For example, when the number of light emitting elements is 800 (800 ch), the correction unit 43 divides the output unit 42 into fifty areas 45-1 to 45-50. In this case, each of the areas 45-1 to 45-50 includes a total of sixteen output pads 44 in four rows and four columns. The correction unit 43 corrects, for each of the areas 45-1 to 45-50, the drive current supplied to the output pads 44 in the areas 45-1 to 45-50.

Hereinafter, when there is no need to indicate a specific area in the areas 45-1 to 45-50, it is simply referred to as an area 45. Further, a row of the area 45 arranged in the X-axis direction from the area 45-1 is described as a first stage, and a row of the area 45 sequentially adjacent to the first stage in the Y-direction is described as a second stage, a third stage, and so on.

In the drive circuit 12, the drive current supplied to each stage and each area 45 can be made close to uniformity by correcting the drive current in each area 45 by the correction unit 43. In other words, the correction unit 43 can reduce an error of the drive current between the stages and between the areas 45.

However, depending on a layout of the drive current supply wiring that supplies the drive current to the output pads 44, the drive circuit 12 may not be able to supply the drive current close to uniformity to the individual output pads 44 in the stage and the area 45.

Therefore, the drive circuit 12 according to the present disclosure includes the drive current supply wiring of a wiring pattern capable of bringing the drive current supplied to the individual output pads 44 in the stage and the area 45 close to uniformity. Next, in order to clarify an effect of the drive current supply wiring according to the present disclosure, a drive current supply wiring according to a comparative example will be described first, and then the drive current supply wiring according to the present disclosure will be described.

### 4. Drive Current Supply Wiring According to Comparative Example

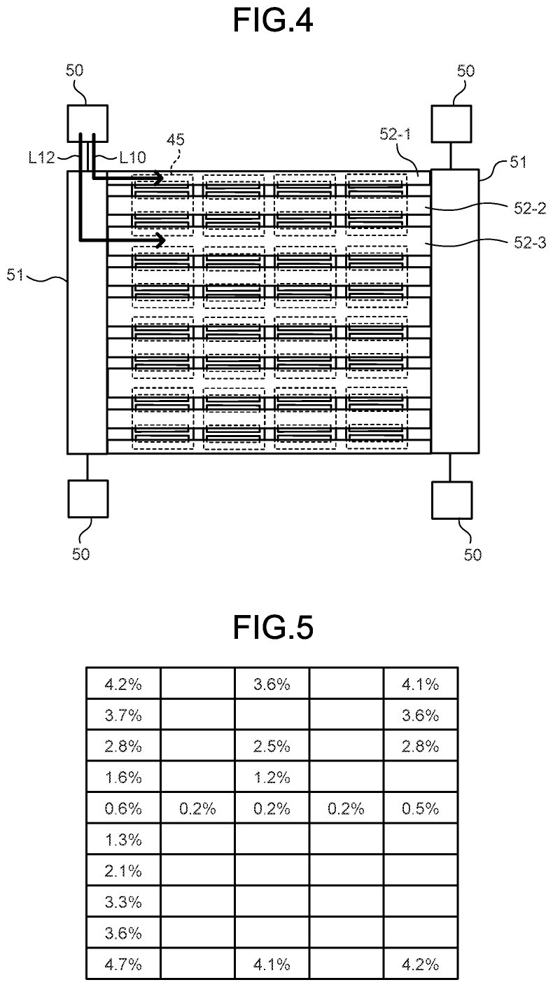

FIG. 4 is a plan view illustrating the drive current supply wiring according to the comparative example. Note that FIG. 4 illustrates sixteen areas 45. FIG. 5 is a table of an error rate of the drive current in each area in which the drive current is supplied to each output pad when the drive current supply wiring according to the comparative example is adopted. Note that FIG. 5 illustrates the error rate when the drive current supply wiring according to the comparative example is adopted for the output unit 42 illustrated in FIG. 3.

Here, the error rate is a ratio of a difference between a maximum value and a minimum value of the drive current actually supplied to each output pad 44 in the area 45 with respect to a drive current value to be supplied to each output pad 44 in the area 45.

As illustrated in FIG. 4, the drive current supply wiring according to the comparative example includes a common wiring 51 extending in parallel with the Y direction on both sides in the X direction of a region where the areas 45 are provided in a matrix. In addition, the drive current supply wiring according to the comparative example includes a plurality of connection wirings 52-1, 52-2, 52-3 and so on connecting the common wirings 51 on both sides in parallel with the X direction.

The common wiring 51 is connected to a power supply pad 50 at both ends in the Y direction. Each of the connection wirings 52-1, 52-2, 52-3 and so on is connected to the output pad 44 in the corresponding area 45. For example, to supply the drive current, the connection wirings 52-1, 52-2, and 52-3 are connected to the output pads 44 provided in the respective areas 45 in the first stage. Note that, to supply the drive current, the connection wiring 52-3 is also connected to the output pad 44 provided in each area 45 in the second stage adjacent to the first stage in the Y direction.

When this drive current supply wiring is adopted, the drive current is supplied, for example, to the output pads 44 in the first stage from the power supply pad 50 provided at upper left in FIG. 4, via the common wiring 51, by a supply path L10 passing through the connection wiring 52-1 and a supply path L12 passing through the connection wiring 52-3.

At this time, since the supply path L12 is longer than the supply path L10, a wiring resistance increases. Therefore, a smaller drive current is supplied to the output pads 44 connected to the connection wiring 52-3 than that of the output pads 44 connected to the connection wiring 52-1.

Moreover, the connection wiring 52-3 also supplies the drive current to the output pads 44 in the second stage. Therefore, a difference between the drive current supplied to the output pads 44 in the first stage connected to the connection wiring 52-3 and the drive current supplied to the output pads 44 connected to the connection wiring 52-1 is further increased.

As a result, the error rate of the drive current supplied to each of the output pads 44 in the areas 45 included in the first stage increases. In addition, since the drive current supplied is larger in the areas 45 closer to the power supply pad 50, the error of the drive current in the area 45 due to a difference in the wiring resistance is larger in the areas 45 closer to four corners of the region in which the areas 45 are provided in a matrix.

As illustrated in FIG. 5, when the drive current supply wiring according to the comparative example is adopted, the error rate of the drive current exceeds 4% in the areas 45 located at the four corners of the region in which the areas 45 are provided in a matrix. As a result, the luminance unevenness increases in the light emitting elements connected to the output pads in the areas 45.

### 5. Drive Current Supply Wiring According to Present Disclosure

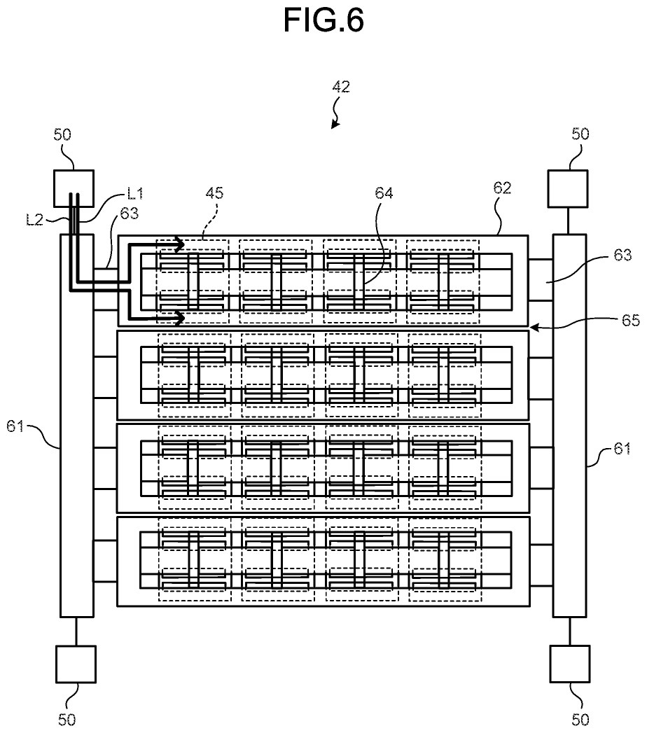

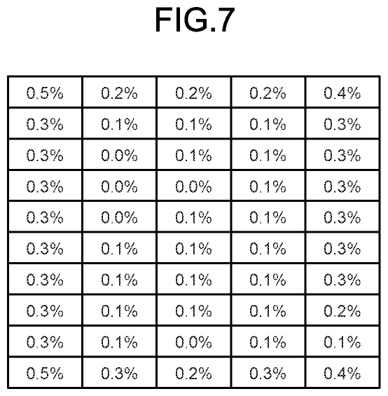

FIG. 6 is a plan view illustrating the drive current supply wiring according to the present disclosure. Note that FIG. 6 illustrates sixteen areas 45. FIG. 7 is a table of an error rate of the drive current in each area in which the drive current is supplied to each output pad when the drive current supply wiring according to the comparative example is adopted. Note that FIG. 7 illustrates the error rate when the drive current supply wiring according to the present disclosure is adopted for the output unit 42 illustrated in FIG. 3.

As illustrated in FIG. 6, the drive current supply wiring according to the present disclosure includes a plurality of annular wirings 62 having a rectangular frame shape, a common wiring 61, and a connection wiring 63. Each of the plurality of annular wirings 62 annularly surrounds the plurality of output pads 44 in a predetermined number of rows (“four” in the example illustrated in FIG. 3) adjacent in the column direction (Y direction) and is connected to the output pads 44 surrounded. The plurality of annular wirings 62 are arranged in the column direction (Y direction) of the output pads 44. In other words, each of the annular wirings 62 annularly surrounds the plurality of output pads 44 in each stage of the area 45.

The common wiring 61 is provided on both sides in a direction (X direction) orthogonal to the arrangement direction (Y direction) of the plurality of annular wirings 62 in plan view and in parallel with the arrangement direction (Y direction), and is connected to the power supply pad 50 at both ends in the Y direction. The connection wiring 63 connects the annular wiring 62 and the common wiring 61.

When this drive current supply wiring is adopted, the drive current is supplied to the output pads 44 in the first stage by two supply paths L1 and L2 from the power supply pad 50 provided at the upper left in the drawing via the common wiring 61 and the connection wiring 63 and passes through the annular wiring 62 branching from the connection wiring 63.

According to the drive current supply wiring of the present disclosure, wiring resistances of the supply paths L1 and L2 can be brought close to uniformity by providing an approximately uniform path length to the two supply paths L1 and L2 that supply the drive current to the output pads 44 in the first stage.

As a result, the drive current supply wiring according to the present disclosure can reduce an error of the drive current supplied to the output pads 44 connected to each of a pair of wiring portions parallel to the X direction configuring both ends of the annular wiring 62 in the Y direction.

Therefore, when the drive current supply wiring according to the present disclosure is adopted, the error rate of the drive current supplied to the output pads 44 included in the first stage can be reduced, so that the luminance unevenness among the light emitting elements connected to the output pads in the area 45 can be suppressed.

In addition, the connection wiring 63 connects the common wiring 61 and a central portion in plan view of a wiring portion parallel to the Y direction configuring both ends in the direction (X direction) orthogonal to the arrangement direction (Y direction) of the annular wirings 62 in plan view.

As a result, since the two supply paths L1 and L2 for supplying the drive current have the same length, an amount of the drive current supplied by the supply path L1 and an amount of the drive current supplied by the supply path L2 can be completely matched. As a result, according to the drive current supply wiring of the present disclosure, the luminance unevenness of the light emitting elements connected to the output pads 44 in each area 45 included in the first stage can be more reliably suppressed.

Furthermore, the annular wirings 62 adjacent to each other in the Y direction is separated by a slit 65. As a result, since each annular wiring 62 does not supply the drive current to both of two adjacent stages, it is possible to uniformly supply the drive current to the plurality of output pads 44 in the region surrounded annularly.

Also in the output pads in the second, third, and fourth stages, the same path length is provided for two drive current paths that enter each of the annular wirings 62 from each of the connection wirings 63 and branch into two. Thus, the luminance unevenness of the light emitting elements connected to the output pads 44 included in the second, third, and fourth stages can be suppressed.

In the drive current supply wiring according to the present disclosure, there is a difference in wiring path length from the power supply pad 50 to the annular wiring 62 in each stage. Therefore, the correction unit 43 corrects the drive current to be supplied to each of the annular wirings 62 so that uniform drive current can be supplied to the stages.

As a result, uniform drive current is supplied by the respective annular wirings 62, and a difference in the drive current between the stages is reduced. Furthermore, the correction unit 43 can also eliminate the difference in the supply current between the areas 45 arranged in the X direction in each stage by correcting the drive current supplied to each area 45.

As a result, the light emitting device 1 can reduce the error of the drive current between the stages and between the areas 45. Therefore, as illustrated in FIG. 7, when the drive current supply wiring according to the present disclosure is adopted, the error rate of the drive current can be suppressed to less than 1% in all the areas 45.

In addition, the drive current supply wiring according to the present disclosure includes a reinforcement wiring 64 that connects the wiring portions parallel to the X direction configuring both ends of each of the annular wirings 62 in the arrangement direction (Y direction). As a result, it is possible to efficiently supply the drive current to each output pad 44 by lowering the wiring resistance of the entire drive current supply wiring.

### 6. Cross-Sectional Structure of Drive Current Supply Wiring

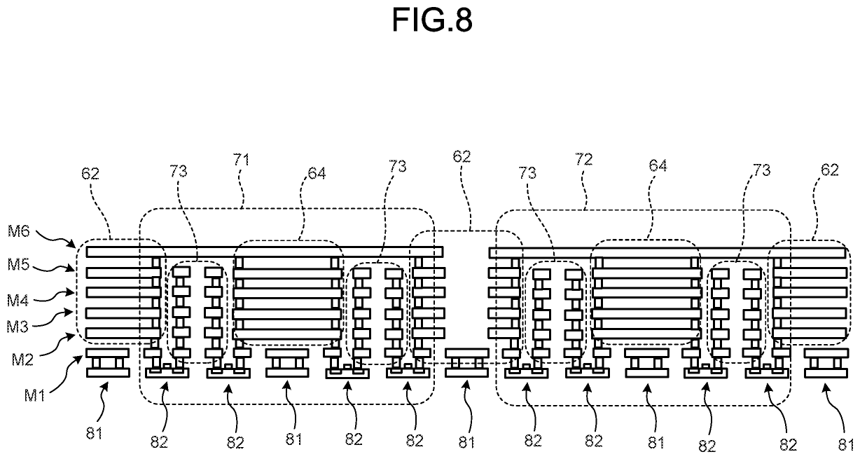

FIG. 8 is a cross-sectional view illustrating the drive current supply wiring according to the present disclosure. FIG. 8 illustrates cross sections of a first stage 71 and a second stage 72 in a cross section obtained by cutting the drive current supply wiring by a line parallel to the Y direction passing through the reinforcement wiring 64 in plan view.

As illustrated in FIG. 8, the annular wiring 62 has a multilayer wiring structure including a first annular wiring M2, a second annular wiring M3, a third annular wiring M4, a fourth annular wiring M5, and a fifth annular wiring M6 laminated on a first wiring layer M1.

Here, the top and bottom of the drive current supply wiring are inverted, but the output unit 42 is provided on the lower surface of the wiring layer where the first wiring layer M1 and the first to fifth annular wirings M2 to M6 illustrated in FIG. 8 are provided. In other words, when mounted, the output unit 42 is stacked on the wiring layer. Interlayers of the first wiring layer M1 and the first to fifth annular wirings M2 to M6 are connected by contacts.

The first wiring layer M1 is connected to a sub-contact 81 and a PMOS transistor 82 via the contact. Furthermore, in a cross-sectional view, an output wiring 73 having a multilayer structure is provided between the annular wiring 62 and the reinforcement wiring 64.

The annular wiring 62 and the reinforcement wiring 64 are connected to a source of the PMOS transistor 82 via the contact and the first wiring layer M1. On the other hand, the output wiring 73 is connected to a drain of the PMOS transistor 82 via the contact and the first wiring layer M1.

The drive circuit 12 applies a negative gate voltage to a gate of the PMOS transistor 82, thereby supplying the drive current from the annular wiring 62 and the reinforcement wiring 64 to the light emitting element via the PMOS transistor 82, the output wiring 73, and the output pad 44 (FIG. 3).

### 7. Modified Example of Cross-Sectional Structure of Drive Current Supply Wiring

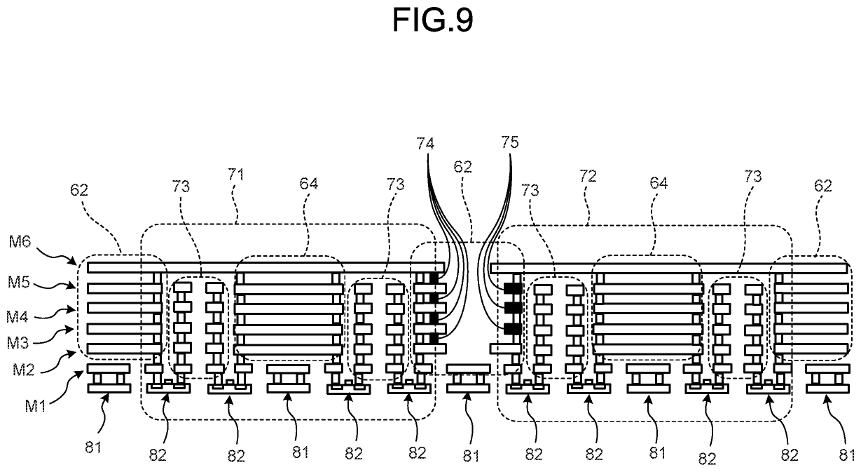

FIG. 9 is a cross-sectional view illustrating a drive current supply wiring according to a modified example of the present disclosure. As illustrated in FIG. 9, in the drive current supply wiring according to the modified example, the wiring resistance of the annular wiring 62 in the first stage can be reduced by further adding a contact 74 connecting the first to fifth annular wirings M2 to M6 in the first stage.

In addition, the drive current supply wiring according to the modified example can increase the wiring resistance in the annular wiring 62 in the first stage by reducing the number of contacts 74 connecting the first to fifth annular wirings M2 to M6 in the first stage.

Therefore, in the drive current supply wiring according to the modified example, the number of contacts 75 connecting the first to fifth annular wirings M2 to M6 between the layers is adjusted for each of the annular wirings 62, so that uniform drive current can be supplied by the respective annular wirings 62. As a result, in the drive current supply wiring, uniform drive current is supplied by the respective annular wirings 62, and a difference in the drive current between the stages can be reduced.

In addition, as illustrated in FIG. 9, in the drive current supply wiring according to the modified example, for example, wiring widths of the second to fourth annular wirings M3 to M5 in the second stage are made narrower than the wiring widths of the first annular wiring M2 and the fifth annular wiring M6, whereby the wiring resistance of the annular wiring 62 in the second stage can be increased.

In addition, the drive current supply wiring according to the modified example can reduce the wiring resistance of the annular wiring 62 in the second stage by expanding the first to fifth annular wirings M2 to M6 in the second stage. Therefore, in the drive current supply wiring according to the modified example, the wiring width of the annular wiring 62 is adjusted for each of the annular wirings 62 so that uniform drive current can be supplied by the annular wirings 62. As a result, in the drive current supply wiring, uniform drive current is supplied by the respective annular wirings 62, and a difference in the drive current between the stages can be reduced.

### 8. Effects

The light emitting device 1 includes the light emitter 11, the output unit 42, and the drive current supply wiring. In the light emitter 11, the plurality of light emitting elements are provided in a matrix in plan view. The output units 42 are provided in a matrix such that the plurality of output pads 44 that outputs the drive current to the light emitting elements overlap the light emitting elements in plan view. The drive current supply wiring is provided in the wiring layer on which the output unit 42 is stacked, and supplies the drive current from the power supply to the light emitting elements via the output pads 44. The drive current supply wiring includes the plurality of annular wirings 62 having a rectangular frame shape, the common wirings 61, and the connection wiring 63. Each of the annular wirings 62 annularly surrounds the plurality of output pads 44 in a predetermined number of rows of output pads 44 adjacent in the column direction, is connected to the output pads 44 surrounded, and is arranged in the column direction of the output pads 44. The common wiring 61 is provided on both sides in the direction orthogonal to the arrangement direction of the plurality of annular wirings 62 in plan view in parallel with the arrangement direction, and is connected to the power supply. The connection wiring 63 connects the annular wiring 62 and the common wiring 61. As a result, the light emitting device 1 can suppress the luminance unevenness in the group of the light emitting elements of several rows adjacent in the column direction corresponding to each stage by making the drive current supplied to the output pad 44 in each stage uniform.

The connection wiring 63 connects the common wiring 61 and the central portion in plan view of the wiring portion configuring both ends of the annular wiring 62 in the direction orthogonal to the arrangement direction in plan view. As a result, the light emitting device 1 can supply further uniform drive current to the output pads 44 in each stage.

The drive current supply wiring further includes the reinforcement wiring 64 that connects wiring portions configuring both ends of the annular wiring 62 in the arrangement direction. As a result, it is possible to efficiently supply the drive current to each output pad 44 by lowering the wiring resistance of the entire drive current supply wiring.

In the drive current supply wiring, the wiring width of the annular wiring 62 is adjusted for each of the annular wirings 62 so that uniform drive current can be supplied by the respective annular wirings 62. As a result, in the drive current supply wiring, uniform drive current is supplied by the respective annular wirings 62, and a difference in the drive current between the stages can be reduced.

The drive current supply wiring includes a plurality of laminated layers of annular wirings 62, and the number of contacts connecting the annular wirings 62 between the layers is adjusted for each of the annular wirings 62 so that the uniform drive current can be supplied by the annular wirings 62. As a result, in the drive current supply wiring, uniform drive current is supplied by the respective annular wirings 62, and a difference in the drive current between the stages can be reduced.

The light emitting device 1 includes the correction unit 43 that corrects the drive current supplied to the predetermined number of rows of the output pads 44. As a result, the correction unit 43 can eliminate the difference in the supply current between the stages by correcting the drive current supplied to each stage.

The light emitting device 1 includes the correction unit 43 that corrects the drive current supplied to a predetermined number of rows and columns of the output pads 44. As a result, the correction unit 43 can eliminate the difference in the supply current between the areas 45 arranged in the X direction in each stage by correcting the drive current to be supplied to each of the areas 45.

The common wiring 61 is connected to the power supply pad 50 at both ends in an extending direction. As a result, the drive circuit 12 can supply uniform drive current to all the output pads 44 in the output unit 42.

Note that the effects described in the present specification are merely examples and not limited, and other effects may be provided.

The present technology can also have the following configurations.

(1)

A light emitting device including:

a light emitter provided with a plurality of light emitting elements arranged in a matrix in plan view;

an output unit provided with a plurality of output pads that outputs a drive current to the plurality of light emitting elements, the plurality of output pads being arranged in a matrix so as to overlap with the plurality of light emitting elements in plan view; and

a drive current supply wiring provided in a wiring layer on which the output unit is stacked, the drive current supply wiring supplying the drive current from a power supply to the plurality of light emitting elements via the plurality of output pads, wherein

the drive current supply wiring includes

a plurality of annular wirings having a rectangular frame shape and arranged in a column direction of the plurality of output pads, each of the plurality of annular wirings annularly surrounding the plurality of output pads in a predetermined number of rows adjacent in the column direction and being connected to the plurality of output pads surrounded,

a common wiring provided on both sides in a direction orthogonal to an arrangement direction of the plurality of annular wirings in plan view and in parallel with the arrangement direction, the common wiring being connected to the power supply, and

a connection wiring that connects the plurality of annular wirings and the common wiring.

(2)

The light emitting device according to (1), wherein

the connection wiring

connects the common wiring and a central portion in plan view of a wiring portion configuring both ends of each of the plurality of annular wirings, the both ends being in a direction orthogonal to the arrangement direction in plan view.

(3)

The light emitting device according to (1) or (2), wherein

the drive current supply wiring further includes

a reinforcement wiring that connects wiring portions configuring both ends, in the arrangement direction, of each of the plurality of annular wirings.

(4)

The light emitting device according to any one of (1) to (3), wherein

the drive current supply wiring has

the plurality of annular wirings whose wiring widths are adjusted individually so as to supply uniform drive current by the plurality of annular wirings.

(5)

The light emitting device according to any one of (1) to (4), wherein

the drive current supply wiring includes

a plurality of layers laminated of the plurality of annular wirings, and a number of contacts connecting the plurality of annular wirings between the plurality of layers is adjusted for each of the plurality of annular wirings so as to supply uniform drive current by the plurality of annular wirings.

(6)

The light emitting device according to any one of (1) to (5), including

a correction unit that corrects the drive current supplied to the predetermined number of rows of the plurality of output pads.

(7)

The light emitting device according to any one of (1) to (5), including

a correction unit that corrects the drive current supplied to a predetermined number of rows and columns of the plurality of output pads.

(8)

The light emitting device according to (1), wherein

the common wiring is

connected to the power supply at both ends in an extending direction.

### REFERENCE SIGNS LIST

1 LIGHT EMITTING DEVICE
11 LIGHT EMITTER
12 DRIVE CIRCUIT
13 POWER SUPPLY CIRCUIT
41 DRIVE CONTROL CIRCUIT
42 OUTPUT UNIT
43 CORRECTION UNIT
44 OUTPUT PAD
45 AREA
50 POWER SUPPLY PAD
61 COMMON WIRING
62 ANNULAR WIRING
63 CONNECTION WIRING
64 REINFORCEMENT WIRING

What is claimed is:

1. A light emitting device, comprising:
a light emitter provided with a plurality of light emitting elements arranged in a matrix in plan view;
an output unit provided with a plurality of output pads that outputs a drive current to the plurality of light emitting elements, the plurality of output pads being arranged in a matrix so as to overlap with the plurality of light emitting elements in plan view; and
a drive current supply wiring provided in a wiring layer on which the output unit is stacked, the drive current supply wiring supplying the drive current from a power supply to the plurality of light emitting elements via the plurality of output pads, wherein
the drive current supply wiring includes
a plurality of annular wirings having a rectangular frame shape and arranged in a column direction of the plurality of output pads, each of the plurality of annular wirings annularly surrounding the plurality of output pads in a predetermined number of rows adjacent in the column direction and being connected to the plurality of output pads surrounded,
a common wiring provided on both sides in a direction orthogonal to an arrangement direction of the plurality of annular wirings in plan view and in parallel with the arrangement direction, the common wiring being connected to the power supply, and
a connection wiring that connects the plurality of annular wirings and the common wiring.

2. The light emitting device according to claim 1, wherein
the connection wiring
connects the common wiring and a central portion in plan view of a wiring portion configuring both ends of each of the plurality of annular wirings, the both ends being in a direction orthogonal to the arrangement direction in plan view.

3. The light emitting device according to claim 1, wherein
the drive current supply wiring further includes
a reinforcement wiring that connects wiring portions configuring both ends, in the arrangement direction, of each of the plurality of annular wirings.

4. The light emitting device according to claim 1, wherein
the drive current supply wiring has
the plurality of annular wirings whose wiring widths are adjusted individually so as to supply uniform drive current by the plurality of annular wirings.

5. The light emitting device according to claim 1, wherein
the drive current supply wiring includes
a plurality of layers laminated of the plurality of annular wirings, and a number of contacts connecting the plurality of annular wirings between the plurality of layers is adjusted for each of the plurality of annular wirings so as to supply uniform drive current by the plurality of annular wirings.

6. The light emitting device according to claim 1, comprising
a correction unit that corrects the drive current supplied to the predetermined number of rows of the plurality of output pads.

7. The light emitting device according to claim 1, comprising
a correction unit that corrects the drive current supplied to a predetermined number of rows and columns of the plurality of output pads.

8. The light emitting device according to claim 1, wherein
the common wiring is
connected to the power supply at both ends in an extending direction.
